(19) United States
(12) Patent Application Publication
(10) Pub. No.: US 2009/0195978 A1
(43) Pub. Date: Aug. 6, 2009

(54) Structure and method for electrically connecting heat dissipating device and adapting circuit board

(75) Inventors: Tiger Hu, Shanhai City (CN); Tsai-Kuei Cheng, Taipei (TW)

Correspondence Address: Edwards Angell Palmer & Dodge LLP, P.O. Box 55874, Boston, MA, 02205, US

(73) Assignee: Inventec Corporation, Taipei City (TW)

(21) Appl. No.: 12/012,759

(22) Filed: Feb. 5, 2008

(51) Int. Cl. H05K 7/20; B23P 11/00

(52) U.S. Cl. 361/679.48; 29/428; 361/679.46

(57) ABSTRACT

A structure and method for electrically connecting a heat dissipating device and an adapting circuit board in an electronic equipment are provided. The electronic equipment has a casing, a motherboard and a hard disk installed in the casing, and an adapting circuit board fixed to the casing. The structure includes a first connector disposed on the adapting circuit board, and a second connector disposed on the heat dissipating device and corresponding to the first connector. The method includes fixing a first connector to the adapting circuit board, wherein the first connector is electrically connected to the adapting circuit board, and the heat dissipating device and the adapting circuit board are electrically connected by plugging the second connector into the first connector so that the heat dissipating device and the adapting circuit board are electrically connected without an electric wire.

### BACKGROUND OF THE INVENTION

1. Field of the Invention

The present invention relates to a structure and method for electrically connecting electronic devices, and more particularly to a structure and method for electrically connecting a heat dissipating device and an adapting circuit board.

2. Description of Related Art

At present, electronic equipments are a standard product integrated by a plurality of hard disks, and have many advantages such as a universal structure size, accommodation of a plurality of hard disks, easy performance of hot pluggable hard disks, a failed disk in the redundant array of inexpensive disks (RAID) to be replaced online, and the like. Therefore, in the field of computers, especially in the field of servers, hard disk module is increasingly and widely applied.

In addition, a hard disk module of an electronic equipment is used for storing important information so as to ensure normal operation of a computer system in a server, for example. Meanwhile, hard disk modules are major heat-generating components in the computer. Along with the rapid development of the computer industry and increasing popularity of electronic information, the hard disk module installed in the computer is getting more and more workload for processing information, and therefore generates more heat. Subsequently, the temperature is getting higher during the operation of the system, and that is easy to cause an unstable situation or a system crash due to overheating. Therefore, heat dissipating devices such as fans are disposed inside the electronic equipment so as to keep the hard disk module working at a stable temperature.

Nowadays, fans applied in servers are disposed at the back of hard disks with a backplane between, and then the backplane drives the fans to dissipate heat generated by the hard disks. Please see FIG. 1. Server 1 comprises a casing 10, a motherboard 11, a hard disk 12, a heat dissipating device 13, and a backplane 14, wherein the backplane 14 is a circuit board and disposed inside the casing 10. Conducting wires 140 are disposed on one side of the backplane 14 and electrically connected to the motherboard 11, and another side of the backplane 14 is electrically connected to the hard disk 12. The motherboard 11 and the hard disk 12 are both disposed inside the casing 10. The heat dissipating device 13 has at least one fan 131, and a space for accommodating a fan prop stand 130 of the fans 131. The fan prop stand 130 has connectors 132 electrically connected to each fan 131. Each of the connectors 132 is connected to one end of an electric wire 16, and the other end of the electric wire 16 is connected to the backplane 14, so that the heat dissipating device 13 is electrically connected to the backplane 14. The motherboard 11 outputs signals to the backplane 14 so that the backplane 14 controls over each of the fans 131 for performing heat dissipation inside the server 1.

However, it is extremely inconvenient in assembly and disassembly of the heat dissipating device 13 because the structure for electrically connecting the heat dissipating device 13 and the backplane 14 needs electric wires for connecting the connectors 132 and the backplane 14. It is also inconvenient in maintenance if one of the fans 131 fails during the operation of the system, the electric wire 16 must be removed, and then is replaced with a new electric wire for connecting the backplane 14 and the connector of a new fan.

Furthermore, a proper gap with a width S needs to be reserved for accommodating the electric wires 16, which connects the heat dissipating device 13 and the backplane 14. Consequently, the cost gets higher because more space is needed inside the casing and the volume of the server 1 is increased as well.

In conclusion, it is desired to have a structure for electrically connecting the heat dissipating device and the backplane that can effectively overcome the drawbacks of the prior arts as mentioned above.

### SUMMARY OF THE INVENTION

In view of the disadvantages of the prior art mentioned above, it is an objective of the present invention to provide a structure for electrically connecting a heat dissipating device and an adapting circuit board that is easily assembled and disassembled, and a method for the same, thereby saving the processing time.

It is another objective of the present invention to provide a structure and a method for electrically connecting a heat dissipating device and an adapting circuit board that lowers the cost.

To achieve the aforementioned and other objectives, the present invention provides a method for electrically connecting a heat dissipating device and an adapting circuit board in an electronic equipment. The electronic equipment includes a casing, a motherboard and a hard disk installed in the casing, and an adapting circuit board fixed to the casing, wherein the motherboard and the hard disk are electrically connected to the adapting circuit board. The method includes the steps of fixing a first connector to the adapting circuit board, wherein the first connector is electrically connected to the adapting circuit board; providing a heat dissipating device with a second connector; and disposing the heat dissipating device in the casing; and moving the heat dissipating device towards the adapting circuit board and plugging the second connector into the first connector, thereby electrically connecting the heat dissipating device to the adapting circuit board.

According to the aforesaid method, a plurality of the first connectors are disposed on the adapting circuit board, and the second connectors are disposed on the heat dissipating device and corresponding to the first connectors in position and number.

According to the aforesaid method, the adapting circuit board is electrically connected to the motherboard via a conducting wire. The heat dissipating device includes a prop stand and a fan installed on the prop stand. The second connector is fixed to the prop stand, and the fan is electrically connected to the second connector.

According to the aforesaid method, the first connector is a male connector, and the second connector is a female connector. Alternatively, the first connector can be a female connector, and the second connector can be a male connector.

According to the aforesaid method, the present invention further provides a structure for electrically connecting the heat dissipating device and the adapting circuit board. The structure includes a first connector disposed on the adapting circuit board, and a second connector disposed on the heat dissipating device corresponding to the first connector. The heat dissipating device is electrically connected to the adapting circuit board by connecting the first connector to the second connector.

According to the aforesaid structure, the adapting circuit board is electrically connected to the motherboard via a conducting wire. The heat dissipating device includes a prop stand and a fan disposed on the prop stand. The second connector is fixed to the prop stand, and the fan is electrically connected to the second connector.

According to the aforesaid structure, the first connector is a male connector, and the second connector is a female connector. Alternatively, the first connector is a female connector, and the second connector is a male connector.

In conclusion, the structure and method of the present invention for electrically connecting the beat dissipating device and the adapting circuit board are provided by connecting the second connector of the heat dissipating device to the first connector of the adapting circuit board, so that the heat dissipating device is electrically connected to the adapting circuit board. An electric wire for electrically connecting the heat dissipating device and the adapting circuit board in the prior art that causes inconvenient disassembly and assembly can be avoided in the present invention. Thus, saving the processing time due to convenient disassembly and assembly is achieved. In addition, since no electric wire is used in the structure and method of the present invention, the casing does not need a space reserved for installing electric wires so as to reduce the volume of the electronic equipment, and efficiently achieve an objective of lowering the cost.

### BRIEF DESCRIPTION OF THE DRAWINGS

The present invention can be more fully understood by reading the following detailed description of the preferred embodiments, with reference made to the accompanying drawings, wherein:

FIG. 1 is a diagram showing a conventional structure for electrically connecting the heat dissipating device and the backplane;

FIG. 2 is a diagram showing a structure for electrically connecting the heat dissipating device and the adapting circuit board in the electronic equipment according to the present invention; and

FIGS. 3a and 3b are 3D diagrams showing the method for electrically connecting the heat dissipating device and the adapting circuit board according to the present invention.

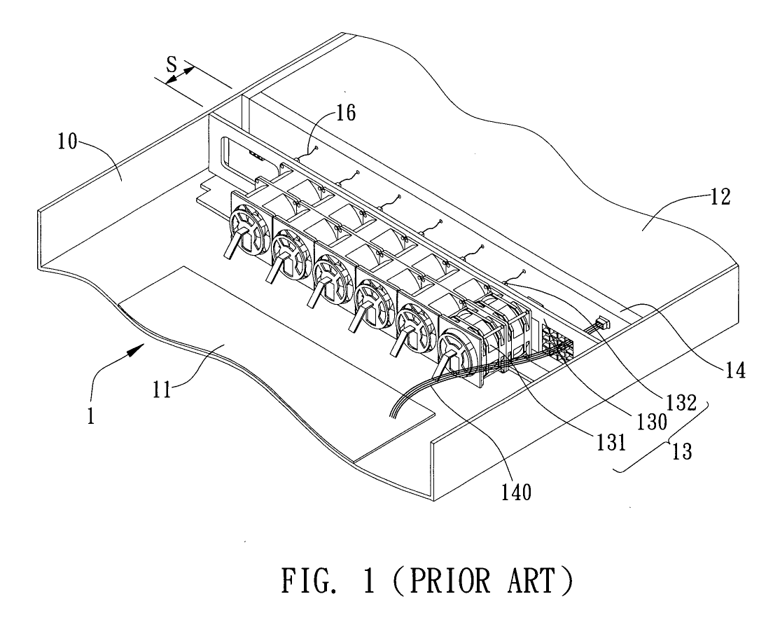

### DETAILED DESCRIPTION OF THE PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

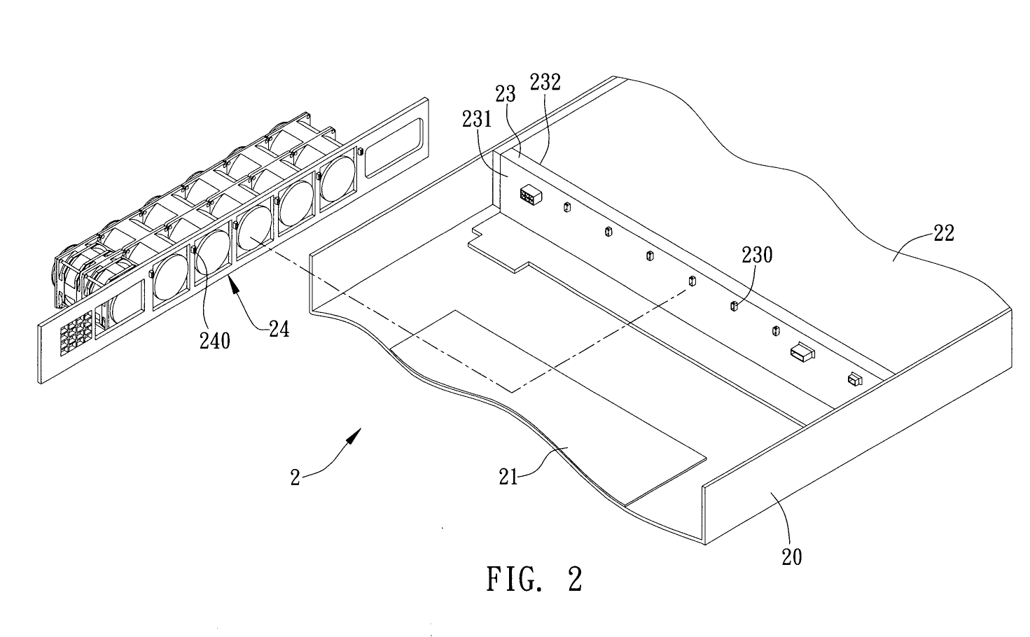

Referring to FIG. 2, it is a diagram showing a structure for electrically connecting a heat dissipating device and an adapting circuit board in an electronic equipment according to the present invention. The electronic equipment 2 can be a device such as a server, a notebook, a personal computer, and the like.

The electronic equipment 2 has a casing 20, a motherboard 21, a hard disk 22, a heat dissipating device 24, and an adapting circuit board 23. The motherboard 21 and the hard disk 22 are installed in the casing 20. The adapting circuit board 23 is fixed to the casing 20 and has a first surface 231 and a second surface 232 opposing to the first surface 231, wherein the second surface 232 is electrically connected to the hard disk 22, and the first surface 231 is electrically connected to the motherboard 21. The structure of the present invention is characterized in that the adapting circuit board has a plurality of the first connectors, and a plurality of second connectors are disposed on the heat dissipating device and corresponding to the first connectors in position and number.

The first connector 230 is a male connector, and the second connector 240 is a female connector so that the structure for the electrical connection is a pluggable structure. The heat dissipating device 24 and the adapting circuit board 23 are electrically connected by plugging the first connector into the second connector. Alternatively, the first connector 230 is a female connector, and the second connector 240 is a male connector. Since connectors can be varied and understood by those skilled in the art, there is no need of further diagrams or detailed descriptions herein.

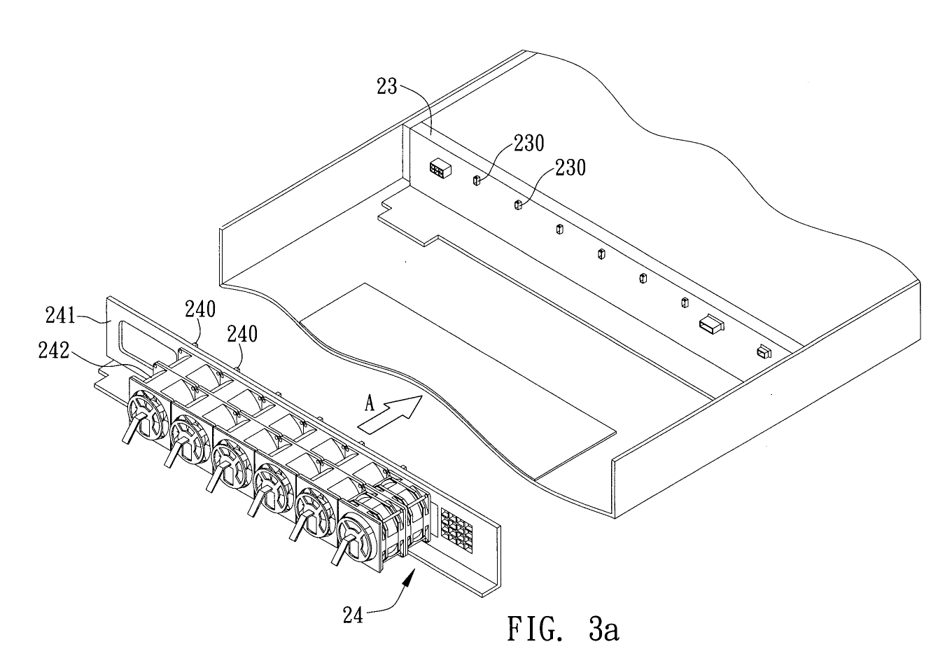

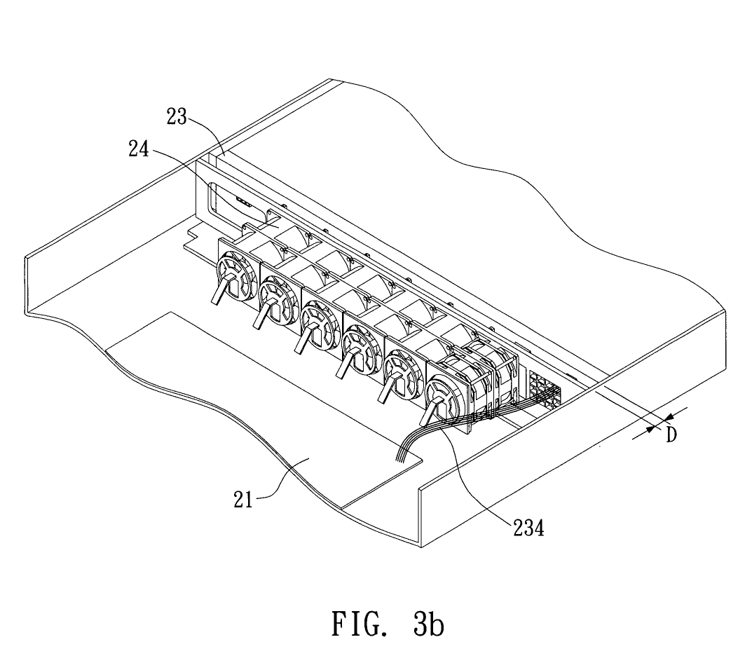

Referring to FIGS. 3a and 3b, the method for electrically connecting the heat dissipating device 24 and the adapting circuit board 23 is illustrated. The method includes the step of: (1) fixing a first connector 230 to a first surface 231 of the adapting circuit board 23, wherein the first connector 230 is electrically connected to the adapting circuit board 23; (2) providing a heat dissipating device 24 with a second connector 240; (3) disposing the heat dissipating device 24 in the casing 20; and (4) moving the heat dissipating device 24 towards the adapting circuit board 23, i.e. pushing the heat dissipating device 2 in a direction A, so that the second connector 240 is plugged into the first connector 230 and thereby the heat dissipating device 24 is electrically connected to the adapting circuit board 23.

Subsequently, the adapting circuit board 23 and the motherboard 21 are electrically connected via a conducting wire 234, and thereby the motherboard 21 transmits signals to the adapting circuit board 23.

The heat dissipating device 24 includes a prop stand 241 and a fan 242 disposed on the prop stand 241. The second connector 240 is fixed to the prop stand 241, and the fan 242 is electrically connected to the second connector 240.

According to the aforesaid structure and method for electrical connection, the heat dissipating device 24 is plugged into the adapting circuit board 23 by plugging the second connector 240 of the heat dissipating device 24 into the first connector 230 of the adapting circuit board 23, and thereby it is easy to perform disassembly and assembly by this pluggable structure. In addition, the pluggable structure does not need the electric wire, and therefore only width D (as shown in FIG. 3b) is needed in the casing 20 for the structure for the electrical connection and a space for the electric wire is not needed, so that the volume of the electronic equipment 2 is reduced.

In conclusion, the structure and method of the present invention for electrically connecting the heat dissipating device and the adapting circuit board are achieved by the pluggable structure between the heat dissipating device and the adapting circuit board. Therefore, saving the processing time due to convenient disassembly and assembly is achieved. In addition, since no electric wire is applied in the pluggable structure, the casing does not need a space reserved for receiving electric wires so as to reduce the volume of the electronic equipment, and efficiently lowering the cost.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method for electrically connecting a heat dissipating device and an adapting circuit board in an electronic equipment, wherein the electronic equipment has a casing, a motherboard and a hard disk installed in the casing, and an adapting circuit board fixed to the casing, wherein the motherboard and the hard disk are electrically connected to the adapting circuit board, the method comprising the steps of:
fixing a first connector to the adapting circuit board, wherein the first connector is electrically connected to the adapting circuit board;
providing a heat dissipating device with a second connector;
disposing the heat dissipating device in the casing; and
moving the heat dissipating device towards the adapting circuit board and plugging the second connector into the first connector, thereby electrically connecting the heat dissipating device to the adapting circuit board.

2. The method for electrically connecting the heat dissipating device and the adapting circuit board of claim 1, wherein the adapting circuit board has a plurality of the first connectors, and the heat dissipating device has a plurality of the second connectors corresponding to the first connectors in position and number.

3. The method for electrically connecting the heat dissipating device and the adapting circuit board of claim 1, wherein the heat dissipating device comprises a prop stand and a fan disposed on the prop stand, the second connector is fixed to the prop stand, and the fan is electrically connected to the second connector.

4. The method for electrically connecting the heat dissipating device and the adapting circuit board of claim 1, wherein the adapting circuit board is electrically connected to the motherboard via a conducting wire.

5. The method for electrically connecting the heat dissipating device and the adapting circuit board of claim 1, wherein the first connector is a male connector, and the second connector is a female connector.

6. The method for electrically connecting the heat dissipating device and the adapting circuit board of claim 1, wherein the first connector is a female connector, and the second connector is a male connector.

7. A structure for electrically connecting a heat dissipating device and an adapting circuit board in an electronic equipment, wherein the electronic equipment has a casing, a motherboard and a hard disk installed in the casing, and an adapting circuit board fixed to the casing, wherein the motherboard and the hard disk are electrically connected to the adapting circuit board, the structure comprising:
a first connector disposed on the adapting circuit board; and
a second connector disposed on the heat dissipating device and corresponding to the first connector,
wherein the heat dissipating device is electrically connected to the adapting circuit board by connecting the first connector and the second connector.

8. The structure for electrically connecting the heat dissipating device and the adapting circuit board of claim 7, wherein a plurality of the first connectors are disposed on the adapting circuit board, and a plurality of the second connectors are disposed on the heat dissipating device and corresponding to the first connectors in position and number.

9. The structure for electrically connecting the heat dissipating device and the adapting circuit board of claim 7, wherein the heat dissipating device comprises a prop stand and a fan installed on the prop stand, the second connector is fixed to the prop stand, and the fan is electrically connected to the second connector.

10. The structure for electrically connecting the heat dissipating device and the adapting circuit board of claim 7, wherein the first connector is a male connector, and the second connector is a female connector.

11. The structure for electrically connecting the heat dissipating device and the adapting circuit board of claim 7, wherein the first connector is a female connector, and the second connector is a male connector.

12. The structure for electrically connecting the heat dissipating device and the adapting circuit board of claim 7, wherein the adapting circuit board is electrically connected to the motherboard via a conducting wire.
